(19) United States
(12) Patent Application Publication
(10) Pub. No.: US 2024/0404869 A1
(43) Pub. Date: Dec. 5, 2024

(54) SOLID-STATE BONDING METHOD FOR THE MANUFACTURE OF SEMICONDUCTOR CHUCKS AND HEATERS

(71) Applicant: WATLOW ELECTRIC MANUFACTURING COMPANY, St. Louis, MO (US)

(72) Inventors: Jason STEPHENS, San Francisco, CA (US); Guleid HUSSEN, San Francisco, CA (US); Michael PARKER, Arnold, CA (US); Dennis REX, Williams, OR (US); Ashish BHATNAGAR, Livermore, CA (US); Brent ELLIOT, Cupertino, CA (US); Kevin PTASIENSKI, O'Fallon, MO (US)

(73) Assignee: WATLOW ELECTRIC MANUFACTURING COMPANY, St. Louis, MO (US)

(21) Appl. No.: 18/804,194

(22) Filed: Aug. 14, 2024

Related U.S. Application Data
(63) Continuation of application No. PCT/US2023/013109, filed on Feb. 15, 2023.
(60) Provisional application No. 63/310,448, filed on Feb. 15, 2022.

(51) Int. Cl. H01L 21/687; B32B 18/00; H01L 21/67; H01L 21/683

(52) U.S. Cl. CPC H01L 21/68785; B32B 18/00; H01L 21/67098; H01L 21/6833; B32B 2255/205; B32B 2457/00

(57) ABSTRACT

A layered assembly for use in a controlled atmosphere chamber includes a plurality of substrates and an electrically functioning layer embedded between two adjacent substrates of the plurality of substrates, the electrically functioning layer being a material configured to secure the two adjacent substrates together using a solid-state bonding process. An electrical termination area is integral with the electrically functioning layer, and a peripheral sealing band is embedded between and extends around a periphery of internal faces of the two adjacent substrates, the peripheral sealing band being a material configured to secure and seal the two adjacent substrates together using the solid-state bonding process. Dielectric regions are present between the two adjacent substrates and between edge boundaries of the electrically functioning layer, the dielectric regions being sealed between the two adjacent substrates by the peripheral sealing band.

### CROSS-REFERENCE TO RELATED APPLICATIONS

This application is a continuation application of International Application No. PCT/US2023/013109, filed on Feb. 15, 2023, which claims priority to and the benefit of U.S. Provisional Application No. 63/310,448, filed on Feb. 15, 2022. The disclosures of the above applications are incorporated herein by reference in their entireties.

### FIELD

The present disclosure relates to pedestals and chucks for use in semiconductor manufacturing equipment, and more specifically to methods of manufacturing such pedestals and chucks having embedded heaters, RF antennas, and clamping electrodes.

### BACKGROUND

The statements in this section merely provide background information related to the present disclosure and may not constitute prior art.

In the processing of semiconductor wafers, a pedestal is arranged within a processing chamber to support a semiconductor substrate. The pedestal is often made from a ceramic material and generally includes a heater plate and a shaft secured to a lower portion of the heater plate. The shaft is hollow and is configured to receive a variety of electrical connections to power the heater plate and to monitor a variety of system parameters throughout the fabrication process.

Some pedestals also include an embedded clamping electrode, which electrostatically secures the semiconductor substrate to a top surface of the pedestal during processing. These types of pedestals are referred to as electrostatic chucks, or ESCs, and operate at an electrical potential ranging from about 300 to thousands of volts. Other pedestals include an embedded RF antenna, which couples an RF power source between the chamber walls and the pedestal or a chucking electrode.

The environment within the processing chamber can be corrosive due to the types of gases being used and the elevated temperatures throughout deposition, etching, doping, and annealing processes. Accordingly, the pedestals must be able to withstand these harsh processing environments, as well as cleaning steps within the chamber after the wafer is removed, while maintaining the integrity of the operational components embedded or disposed therein, i.e., heater, clamping electrode, and RF antenna, among others.

The present disclosure addresses challenges related to the manufacture of pedestals and other ceramic assemblies being operated in harsh chemical environments.

### SUMMARY

This section provides a general summary of the disclosure and is not a comprehensive disclosure of its full scope or all of its features.

In one form of the present disclosure, layered assembly for use in a controlled atmosphere chamber comprises a plurality of substrates, at least one electrically functioning layer embedded between two adjacent substrates of the plurality of substrates, the electrically functioning layer comprising a material configured to secure the two adjacent substrates together using a solid-state bonding process, at least one electrical termination area integral with the at least one electrically functioning layer, and at least one peripheral sealing band embedded between and extending around a periphery of the internal faces two adjacent substrates. The at least one peripheral sealing band comprising a material configured to secure and seal the two adjacent substrates together using the solid-state bonding process, and a plurality of dielectric regions are present between the two adjacent substrates and between edge boundaries of the at least one electrically functioning layer, the plurality of dielectric regions being sealed between the two adjacent substrates by the at least one peripheral sealing band.

In variations of this layered assembly, which may be implemented individually or in any combination: the material of the electrically functioning layer comprises nickel, and in one form the nickel is in an amount greater than 50 at. % and in another form is in an amount greater than 99 at. %; the material of the peripheral sealing band comprises nickel, and in one form the nickel is in an amount greater than 50 at. % and in another form is in an amount greater than 99 at. %; the material of the electrically functioning layer and the material of the peripheral sealing band are the same material; the material of the electrically functioning layer and the material of the peripheral sealing band comprises nickel, and in one form the nickel is in an amount greater than 50 at. % and in another form is in an amount greater than 99 at. %; the material of the electrically functioning layer is graded and has variable material properties along at least one dimension; the electrically functioning layer is selected from the group consisting of a resistive heater, an RF antenna, and a clamping electrode; the electrically functioning layer is a resistive heater and a temperature sensor; each of the plurality of substrates comprise a ceramic material; the two adjacent substrates comprise the same ceramic material; the layered assembly further comprises an upper substrate disposed on one of the two adjacent substrates, the upper substrate comprising a different ceramic material than the ceramic material of the two adjacent substrates; the two adjacent substrates are an aluminum nitride (AlN) material and the upper substrate is a high-grade AlN material; the plurality of substrates comprise a beryllium oxide (BeO) material; the two adjacent substrates comprise a plurality of apertures formed therethrough and the layered assembly further comprises local sealing bands disposed around a periphery of each of the plurality of apertures between the two adjacent substrates; the material of the local sealing bands comprises nickel, and in one form is in an amount greater than 50 at. %. and in another form is in an amount greater than 99 at. %; the material of the electrically functioning layer, the material of the peripheral sealing band, and the material of the local sealing bands are the same material; further comprising an adhesion layer disposed between at least one of the two adjacent substrates and the at least one electrically functioning layer; the adhesion layer is further disposed between at least one of the two adjacent substrates and the at least one peripheral sealing band; the layered assembly further comprises two electrically functioning layers embedded between two adjacent substrates of the plurality of substrates, each electrically functioning layer applied to each of the two adjacent substrates prior to the solid-state bonding process; each electrically functioning layer comprises a trace, and a trace of one electrically functioning layer is wider than a trace of the other electrically functioning layer; the layered assembly further comprises two peripheral sealing bands embedded between two adjacent substrates of the plurality of substrates, each peripheral sealing band applied to each of the two adjacent substrates prior to the solid-state bonding process; a band width of one peripheral sealing band is wider than a band width of the other peripheral sealing band; a plurality of material islands are disposed within the dielectric regions, wherein the material islands are not electrically live; the at least one electrically functioning layer is sputtered onto at least one of the two adjacent substrates; the at least one electrically functioning layer is a foil material; a shaft is secured to a lower side of one of the two adjacent substrates; a joining layer is disposed between the shaft and the lower side of the adjacent substrate, the material of the joining layer comprises nickel, and in one form the nickel is in an amount greater than 50 at. %, and in another form the nickel is in an amount greater than 99 at. %; the seal is hermetic; the at least one electrically functioning layer comprises a resistive heater having a plurality of zones; a plurality of zones of resistive heaters are disposed in different layers within the plurality of substrates.

In another form of the present disclosure, a heater assembly for use in a semiconductor processing chamber comprises an upper substrate, at least two adjacent substrates secured to a lower surface of the upper substrate, at least one resistive heater embedded between the two adjacent substrates, the at least one resistive heater comprising a nickel material configured to secure the two adjacent substrates together using a solid-state bonding process, at least one electrical termination area integral with the at least one resistive heater, and at least one peripheral sealing band embedded between and extending around a periphery of internal faces of the two adjacent substrates, the at least one peripheral sealing band comprising a nickel material configured to secure and seal the two adjacent substrates together using the solid-state bonding process. A plurality of dielectric regions are present between the two adjacent substrates and between edge boundaries of the resistive heater, the plurality of dielectric regions being sealed between the two adjacent substrates by the at least one peripheral sealing band. A shaft is secured to a lower side of one of the two adjacent substrates with a joining layer, the joining layer comprising a nickel material.

In a variation of this heater assembly, an RF antenna is embedded between the upper substrate and one of the two adjacent substrates, the RF antenna comprising a nickel material configured to secure the upper substrate to the adjacent substrate together using the solid-state bonding process.

In yet another form, a layered assembly for use in a controlled atmosphere chamber comprises at least two adjacent substrates, at least one peripheral sealing band embedded between and extending around a periphery of internal faces of the two adjacent substrates, the at least one peripheral sealing band comprising a nickel material configured to secure and seal the two adjacent substrates together using a solid-state bonding process.

In still another form, a heater assembly for use in a semiconductor processing chamber comprises a heater plate, a shaft secured to a lower side of the heater plate, and at least one peripheral sealing band embedded between and extending around a periphery of internal faces of the heater plate and the shaft, the at least one peripheral sealing band comprising a nickel material configured to secure and seal the heater plate and the shaft together using a solid-state bonding process.

According to another form of the present disclosure, a method of forming a layered assembly for use in a controlled atmosphere chamber, the layered assembly comprising a plurality of substrates, comprises applying a material to at least one face of two adjacent substrates of the plurality of substrates, the material being patterned as an electrically functioning layer and with integral electrical termination areas and a peripheral sealing band disposed around a periphery of the at least one face of the two adjacent substrates, and joining the plurality of substrates with heat and pressure in a controlled environment such that the material is solid-state bonded to the two adjacent substrates to secure the two adjacent substrates together to form the layered assembly, the layered assembly being sealed. A plurality of dielectric regions are present between the two adjacent substrates within electrically functioning layer, the plurality of dielectric regions being sealed within the electrically functioning layer by the peripheral sealing element.

In variations of this method, which may be implemented individually or in any combination: the peripheral sealing band is patterned in a separate step from patterning the electrically functioning layer; the material is patterned with a laser; the material is patterned with a mask; the material is patterned with an additive manufacturing process; the material is patterned with an etch process; the material is patterned with a waterjet; the material is patterned with a hybrid laser-waterjet; the material is nickel and is applied with a sputtering process; the nickel material is at least 50 at. %; the nickel material is at least 99 at. %; the material is applied to both faces of the two adjacent substrates; the pressure is controlled to adjust a size of the dielectric regions; and an adhesion layer is applied to the at least one face of the adjacent substrates before applying the material.

In still another form of the present disclosure, a layered assembly for use in a controlled atmosphere chamber comprises a plurality of substrates, at least one electrically functioning layer embedded between two adjacent substrates of the plurality of substrates, the electrically functioning layer comprising a material configured to secure the two adjacent substrates together using a solid-state bonding process, and at least one electrical termination area integral with the at least one electrically functioning layer. A plurality of dielectric regions are present between the two adjacent substrates and between edge boundaries of the at least one electrically functioning layer.

In a variation of this layered assembly, at least one peripheral sealing band is embedded between and extends around a periphery of the internal faces two adjacent substrates, the at least one peripheral sealing band comprising a material configured to secure and seal the two adjacent substrates together using the solid-state bonding process, the plurality of dielectric regions are sealed between the two adjacent substrates by the at least one peripheral sealing band.

In another form, a method of forming a layered assembly for use in a controlled atmosphere chamber, the layered assembly comprising a plurality of substrates, comprises applying a material to at least one face of two adjacent substrates of the plurality of substrates, the material being patterned as an electrically functioning layer and with integral electrical termination areas, and joining the plurality of substrates with heat and pressure in a controlled environment such that the material is solid-state bonded to the two adjacent substrates to secure the two adjacent substrates together to form the layered assembly, the layered assembly being sealed. A plurality of dielectric regions are present between the two adjacent substrates within electrically functioning layer.

In variations of this method, which may be implemented individually or in any combination: the material is applied to at least one face of the two adjacent substrates is also a peripheral sealing band patterned and disposed around a periphery of the at least one face of the two adjacent substrates, and the plurality of dielectric regions are sealed within the electrically functioning layer by the peripheral sealing element; the material is applied to each opposed face of the two adjacent substrates and a pattern of the electrically functioning layer on one opposed face is different than a pattern of the electrically functioning layer on other opposed face; and the electrically functioning layer is a resistive heater and a pattern on one opposed face comprises an unheated region.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a perspective view of a pedestal for use in a semiconductor processing chamber constructed in accordance with the teachings of the present disclosure;

FIG. 2 is a side view of the pedestal of FIG. 1;

FIG. 3 is an exploded view of the pedestal of FIG. 1;

FIG. 4 is a perspective view of a resistive heater layer of FIG. 3 and constructed in accordance with the teachings of the present disclosure;

FIG. 5 is a top view of the resistive heater layer of FIG. 4;

FIG. 6 is a perspective view of an RF antenna layer of FIG. 3 and constructed in accordance with the teachings of the present disclosure;

FIG. 7 is a top view of the RF antenna layer of FIG. 6;

FIG. 8A is a cross-sectional view taken along line 8A-8A of FIG. 1;

FIG. 8B is a detail view taken from FIG. 8A, illustrating an aperture extending through substrates of the pedestal and various layers constructed according to the teachings of the present disclosure;

FIG. 9 is a flow diagram of a manufacturing method according to the teachings of the present disclosure;

FIG. 10A is a top view of a resistive heater layer having a trace pattern constructed according to the teachings of the present disclosure; and

FIG. 10B is a top view of another resistive heater layer having a different trace pattern, which is formed together with the resistive heater layer of FIG. 10A and constructed according to the teachings of the present disclosure.

The drawings described herein are for illustration purposes only, are not necessarily to scale, and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

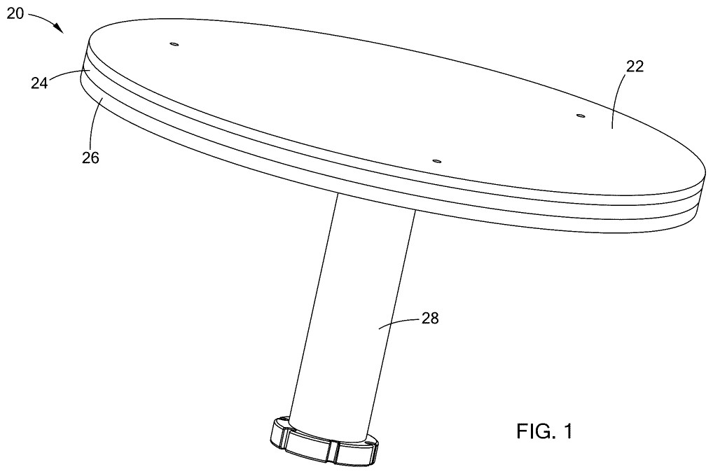

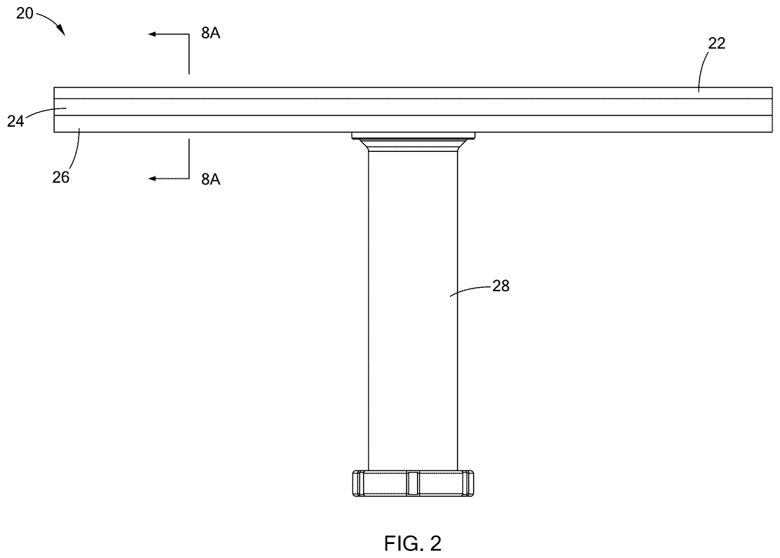

Referring to FIGS. 1-2, a heater assembly for use in a semiconductor processing chamber is illustrated and generally indicated by reference numeral 20. In this form, the heater assembly 20 is also referred to as a “pedestal.” The heater assembly 20 comprises an upper substrate 22, at least two adjacent substrates 24 and 26 secured to a lower surface of the upper substrate 22, and a shaft 28 secured to a lower side of one of the two adjacent substrates 26. Each of the upper substrate 22 and the two adjacent substrates 24 and 26 in one form are a ceramic material. The ceramic material may be the same for each of the substrates or may be different depending on specific application requirements. For example, in one form, each of the substrates (22, 24, 26) and the shaft 28 is an aluminum nitride (AlN) material. In another form, the upper substrate 22 is a high-grade aluminum nitride (AlN) material, having different material properties such as higher volume resistivity, and each of the two adjacent substrates 24 and 26 and the shaft 28 are an aluminum nitride (AlN) material. In another form, the lower adjacent substrate 26 is a material that has a lower thermal conductivity than the other/upper adjacent substrate 24, such as by way of example an aluminum oxide (Al₂O₃) material. In another form, each of the upper substrate 22, the two adjacent substrates 24 and 26, and the shaft 28 are a beryllium oxide (BeO) material. These and other variations of materials for each of the substrates (22, 24, 26) and the shaft 28 should be construed as falling within the scope of the present disclosure.

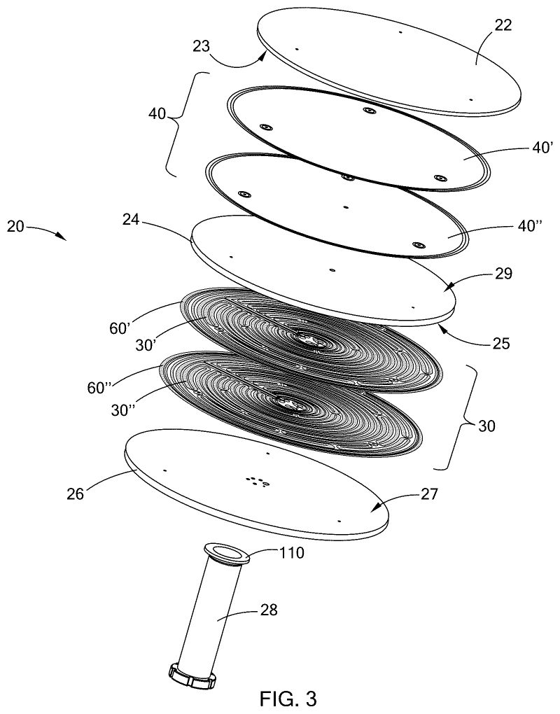

Referring now to FIG. 3, at least one electrically functioning layer is embedded between the substrates (e.g., 22/24/26), wherein the electrically functioning layer is configured to secure the substrates together using a solid-state bonding process, which is described in greater detail below. Advantageously, in one form of the present disclosure, the electrically functioning layer serves a dual function, namely, to secure the substrates together and to provide an electrical function within the heater assembly 20. This electrical function may include, by way of example, a resistive heater, an antenna (e.g., an RF antenna), or a clamping electrode, among others. And in a more general sense, the teachings of the present disclosure may be applied to any layered assembly (i.e., not limited to the heater assembly 20 as illustrated and described herein) for use in a controlled atmosphere chamber while remaining within the scope of the present disclosure.

In one form, the electrically functioning layer is a resistive heater 30. The resistive heater 30 in this form is illustrated in two layers 30′ and 30″ and comprises a nickel material. The two layers 30′ and 30″ are applied separately to each internal face 25 and 27 of the two adjacent substrates 24 and 26 in a manufacturing process described in greater detail below. It should be understood, however, that the resistive heater 30 may be applied in a single layer to either internal face 25 or 27 while remaining within the scope of the present disclosure. As shown, the resistive heater 30 is generally in the form of a trace, or plurality of traces, which are individual continuous tracks of conductive/resistive material (e.g., nickel) that provide a predetermined resistance per unit length. The specific design of the traces (material(s) and dimensions) result in a customizable watt density for a given input power. These traces may also be provided in a plurality of zones as described in greater detail below.

As further shown, another electrically functioning layer in this form is an RF antenna 40. Similar to the resistive heater 30, the RF antenna 40 is in two layers 40′ and 40″ and comprises a nickel material. The two layers 40′ and 40″ are applied separately to an upper face 29 of one of the two adjacent substrates 24 and to a lower face 23 of the upper substrate 22 in a manufacturing process described in greater detail below. It should be understood, however, that the RF antenna 40 may be applied in a single layer to either the upper face 29 or the lower face 23 while remaining within the scope of the present disclosure.

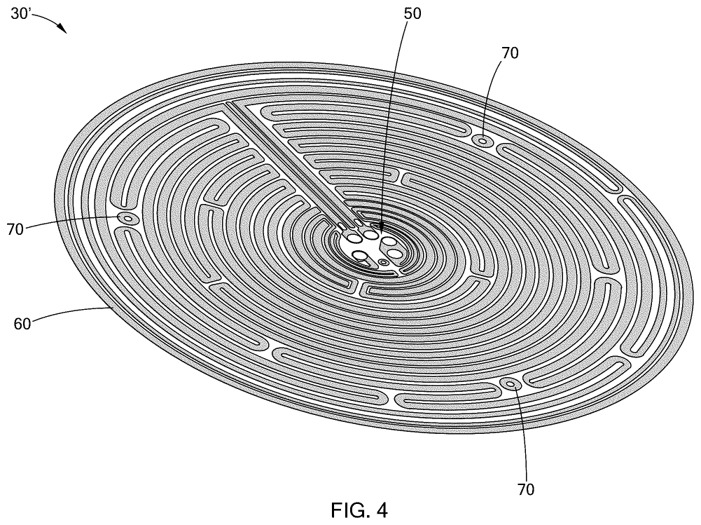

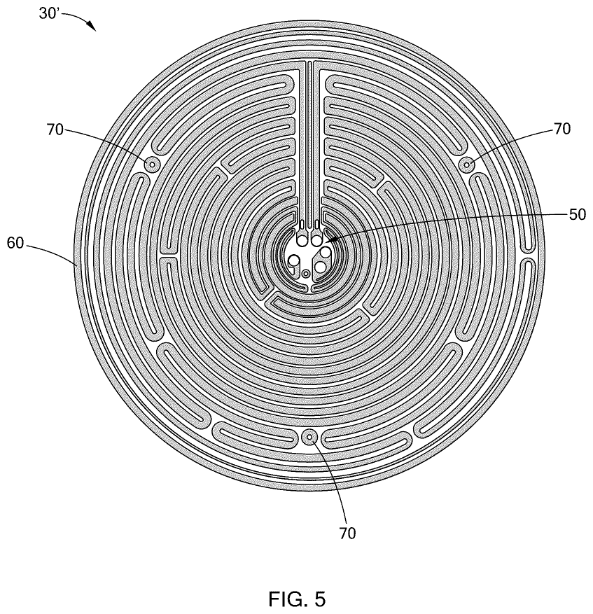

Referring now to FIGS. 4 and 5, at least one electrical termination area 50 is integral with the resistive heater 30 (only one resistive heater layer 30′ is shown for clarity). As used herein, the term “integral” should be construed to mean that the termination area is a part of and is electrically continuous with the resistive heater 30. In one form, this integral construction includes the termination area being the same material as the resistive heater 30, however, different materials may be employed while remaining within the scope of the present disclosure. The electrical termination area 50 in this form is disposed within a central region of the resistive heater 30 layer and is configured to electrically connect the resistive heater 30 to power leads (not shown) extending through a central portion of the shaft 28. In alternate forms, the electrical termination area 50 is not in the central portion of the shaft 28 and is instead located in other regions of the resistive heater 30, particularly with multiple heater zones. In this exemplary form, the electrical termination area includes four (4) total terminations for a two (2) zone heater as shown. It should be understood, however, that a single zone or multiple zones can be employed while remaining within the scope of the present disclosure. Further, the heater assembly 20 may include additional substrates (not shown) such that a plurality of heater zones are disposed in different layers within the plurality of substrates. Such a construction is shown in co-pending application Ser. No. 16/196,820, which is commonly assigned with the present application and the contents of which are incorporated herein by reference in its entirety.

As further shown, at least one peripheral sealing band 60 is embedded between and extends around a periphery of the resistive heater 30. The peripheral sealing band 60 is configured to secure and seal the two adjacent substrates 24 and 26 together using the solid-state bonding process. Therefore, the peripheral sealing band 60 is also serving a dual purpose, namely, to secure the two adjacent substrates 24 and 26 and also to seal the interface therebetween. In one form, the seal is hermetic to meet application requirements within the processing chamber. The hermeticity, or leak rate, in one form is less than about 1×10-6 atm cc/sec (standard cubic centimeters per second) He. In another form, the leak rate is less than about 1×10-7 atm cc/sec He, and still in another form, the leak rate is less than about 1×10.9 atm cc/sec He. Similar to the resistive heater 30 and RF antenna 40, the peripheral sealing band 60 is in two layers 60′ and 60″ (FIG. 3) and comprises a nickel material. The two layers 60′ and 60″ are applied separately to each internal face 25 and 27 of the two adjacent substrates 24 and 26 as described in greater detail below. It should be understood, however, that the peripheral sealing band 60 may be applied in a single layer to either internal face 25 or 27 while remaining within the scope of the present disclosure.

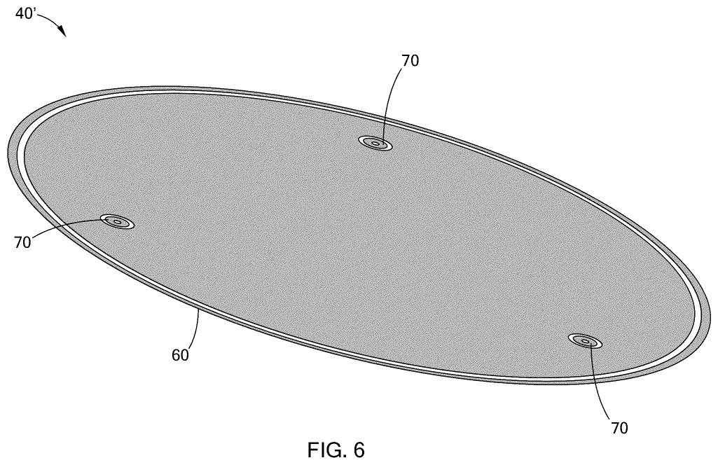

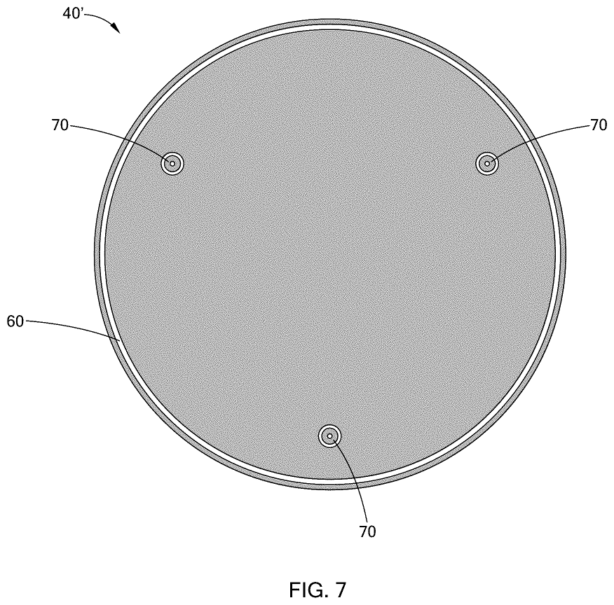

Referring also to FIGS. 6 and 7, a layer 40′ of the RF antenna 40 is shown in greater detail, which also includes the peripheral sealing band 60. The peripheral sealing band 60 in the layer of the RF antenna 40 is applied and functions the same as the peripheral sealing band 60 described above relative to the resistive heater 30. The RF antenna 40 is generally a continuous layer of material as shown but may also take on other patterns while remaining within the scope of the present disclosure. For example, other patterns may include a mesh pattern for the RF antenna. Further, the RF antenna 40 layer may include two or more electrically independent/isolated sections, or zones (not shown), or other patterns such as a grid, while remaining within the scope of the present disclosure. In this form with two or more zones, the electrically functioning layer may also be a chucking electrode. As further shown in both of the layers of the resistive heater 30 and the RF antenna 40, local sealing bands 70 are provided, which are disposed around a periphery of apertures that extend through the substrates.

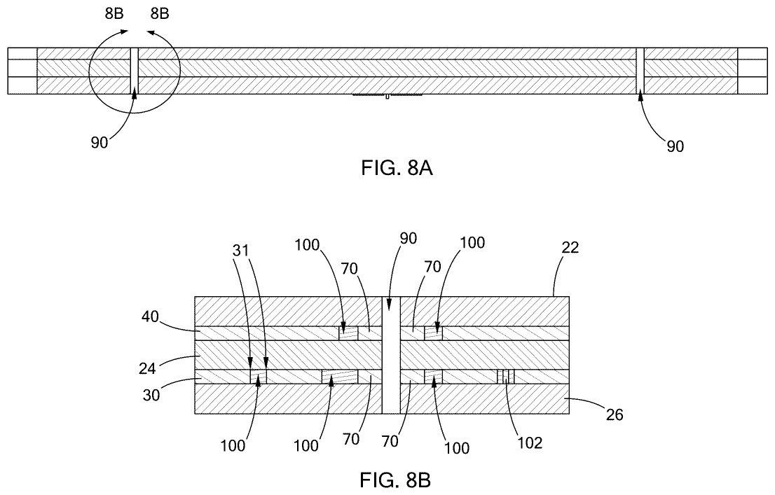

More specifically, and with reference to FIGS. 8A and 8B, a plurality of apertures 90 extend through the substrates (22, 24, 26), which are configured to accommodate lift pins (not shown). The local sealing bands 70 in each of the layers (resistive heater 30 layer and RF antenna 40 layer) function to seal an interface between the substrates (22, 24, 26) local to each of the apertures 90. The local sealing bands 70, which in one form are the same material as the layer to which they are located, also function to secure the substrates (22, 24, 26) to each other local to the apertures 90, thereby also providing a dual-function. Various methods of application and patterning of the local sealing bands 70, the peripheral sealing band 60, the resistive heater 30, and the RF antenna 40 are described in greater detail below.

As further shown in FIGS. 8A and 8B, a plurality of dielectric regions 100 are present between the two adjacent substrates 24 and 26 and between edge boundaries 31 of the resistive heater 30. In another form, the dielectric regions 100 are also present between the upper substrate 22 and one of the two adjacent substrates 24. The dielectric regions 100 are sealed between the substrates (22, 24, 26) by the peripheral sealing band 60, and in some areas the local sealing bands 70 as well. The dielectric regions 100 generally function to dielectrically separate traces of the resistive heater 30 from each other (to inhibit arcing and shorting), to dielectrically separate the apertures 90, and the peripheral sealing element 60, and any other feature within the layer that should not be electrically “live” when the resistive heater 30 is electrically “live.” Similarly, for the RF antenna 40 layer, the dielectric regions 100 dielectrically separate the apertures 90 and the peripheral sealing band 60 from being electrically “live” when the RF antenna 40 is electrically “live,” as well as separate electrically independent/isolated sections of the RF antenna 40 in the form of multiple sections/zones (not shown).

In a variation of the present disclosure, a plurality of material islands 102 are provided within the dielectric regions 100, which are areas of material that are not electrically live and thus contribute to the bonding of the substrates 22, 24, and 26.

With the dielectric regions 100 and the various electrically functioning layers (e.g., resistive heater 30, RF antenna 40), the present disclosure also provides a layered assembly in which the substrates (e.g., 22, 24, 26) are not in physical contact with each other, in one form of the present disclosure.

Referring back to FIG. 3, the shaft 28 is secured to a lower side of one of the two adjacent substrates 26 with a joining layer 110. In one form, the joining layer 110 is also a nickel material, however, it should be understood that other materials may be employed while remaining within the scope of the present disclosure.

As set forth above, in one form of the present disclosure, each of the resistive heater 30, the RF antenna 40, the peripheral sealing element 60, the local sealing bands 70, the material islands 102, and the joining layer 110 for the shaft 28 are a nickel material. Nickel is employed in this form due to its compatible material properties with the specific design of the heater assembly 20 and its manufacturing processes as set forth in greater detail below, as well as its ability to function electrically for the resistive heater 30 and RF antenna 40 within the controlled atmosphere chamber. More specifically, nickel has an electrical conductivity that provides for relatively low profile electrically functioning elements (i.e., resistive heater 30, RF antenna 40, et al.), which can be integrated more easily into the pedestal design. Nickel also has a relatively high TCR (temperature coefficient of resistance) that allows the electrically functioning elements (i.e., resistive heater 30, RF antenna 40, et al.) to also function as temperature sensors (described in greater detail below). Further, nickel can operate at relatively high temperatures, namely, up to about 1,400° C., and in other forms at 650° C., 800° C., or 900° C. among other operating temperature targets. Nickel is also a material that is compatible with controlled atmosphere chambers such as semiconductor processing chambers. Nickel also has a relatively compatible CTE (coefficient of thermal expansion) in the controlled chamber environment relative to ceramic substrates, and more specifically can accommodate CTE mismatches and thermal cycling while maintaining its material properties. Further still, nickel is also compatible relative to the inventive manufacturing processes used to apply the nickel material, which are described in greater detail below. The nickel material in one form is an alloy composition having nickel in an amount greater than about 50 at. %. In another form, the nickel is in an amount greater than about 99 at. %, and even more particularly between 99 at. %-99.999 at. % and less than 0.1 at. % carbon. Although nickel is used with each of the elements as set forth herein, it should be understood that other materials, and material combinations may be employed while remaining within the scope of the present disclosure. Further, a graded material may be employed, which has variable material properties (e.g., resistivity) along at least one dimension, such as by way of example through its thickness, across its width, or along its length. These variable material properties may be designed into the materials or may be a result of a manufacturing process such as hot pressing. For example, the resistive layer 30 may be a nickel material while the RF antenna 40 is an aluminum material, and further yet while the peripheral sealing band 60 and/or local sealing bands 70 are the same or a different material such as titanium. These and other combinations of materials should be construed as falling within the scope of the present disclosure.

In still another form, the nickel material (or other material of the electrically functioning layer) functions as a sensor and provides temperature information. Generally, changes in resistance of the material are monitored and temperatures are calculated (or determined from a look-up table) based on the changes in resistance. Exemplary methods, systems, and controllers for such a dual-function electrically functioning layer are described in greater detail in U.S. Pat. No. 7,196,295, which is commonly owned with the present application and the contents of which are incorporated herein by reference in its entirety.

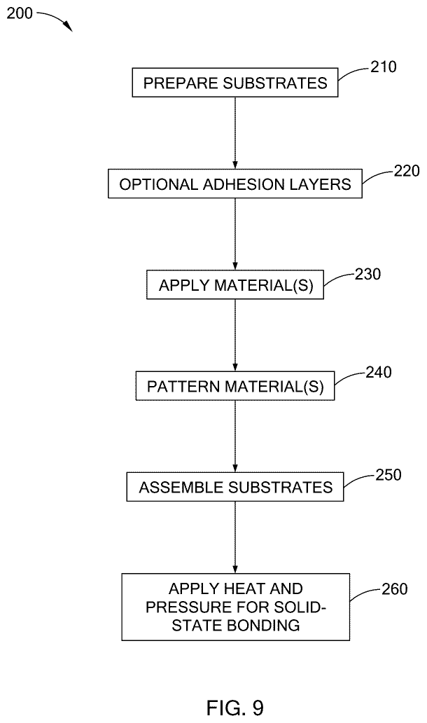

Referring now to FIG. 9, and also to FIG. 3, a method of manufacturing the heater assembly 20 is illustrated and generally indicated by reference numeral 200. In a first step 210, the substrates 22, 24, and 26 are prepared. More specifically, the substrates 22, 24, and 26 are ground or finished to predetermined flatness and parallel dimensions, which is on the order of about 0.0004 in. (0.01 mm). Next, each of the layers for the resistive heater 30, the RF electrode 40, and the joining layer 110 for the shaft 28 are applied to the faces of the substrates (22, 24, 26) and the shaft 28 in step 230. In an optional step as shown in 220, an adhesion layer (not shown) may be applied to the faces of the substrates/faces as specific materials and processing requirements dictate. For example, if the surface roughness of the adjacent substrates 24/26 is low or if BeO is being used as a material for the substrates (22, 24, 26), to which nickel does not as readily adhere to as other substrate materials (e.g., AlN), then an adhesion layer would be used. In the specific example of BeO substrates, a titanium (Ti) adhesion layer would be used between the nickel and the BeO. Therefore, an adhesion layer would be used if the bonding surface of the substrate is mechanically too smooth or if a material of the substrate does not as readily adhere with the joining/bonding material. Materials for the adhesion layer may include, by way of example, nickel (Ni), aluminum (Al), zirconium (Zr), titanium (Ti), and hafnium (Hf), among others.

In one form, a continuous layer of material (e.g., nickel) is applied to each of the internal faces 25 and 27 of the adjacent substrates 24 and 26, and also the upper face 29 of one of the two adjacent substrates 24 and to a lower face 23 of the upper substrate 22. As set forth above, in one form, the two layers 30′ and 30″ that form the resistive heater 30 are applied separately to each internal face 25 and 27 of the two adjacent substrates 24 and 26 and are mirror images. Similarly, the two layers 40′ and 40″ that form the RF antenna 40 are applied separately to an upper face 29 of one of the two adjacent substrates 24 and to a lower face 23 of the upper substrate 22. This application approach is also referred to as a “double-sided” or “two-sided” application. As set forth above, a single-sided application for the entire layer is within the teachings of the present disclosure. In preliminary testing, the “double-sided” application has been shown to provide improved hermetic sealing for the overall heater assembly 20. The joining layer 110 is applied as a single layer to the upper surface of the shaft 28, in a continuous layer with no patterning, in one form of the present disclosure.

Advantageously, the materials are applied using a sputtering process. It should be understood, however, that other application methods such as chemical vapor deposition (CVD), physical vapor deposition (PVD), thick film, thin film, sol gel, thermal spray, continuous foil, and patterned foil, and combinations thereof, are considered to be within the scope of the present disclosure.

In one form, each layer of material is applied as a continuous layer and subsequently patterned (step 240) to form the various elements of the layer, i.e., resistive heater 30, RF antenna 40, peripheral sealing band 60 and/or local sealing bands 70, and material islands 102. In one form, this patterning is achieved by laser ablation, or laser removal. Other forms of material removal should be construed as falling within the scope of the present disclosure, such as by way of example, chemical etching, water-jet, hybrid water-jet (water-jet and laser), and mechanical grinding, among others. In another form, a mask can be used for one or more layers and the material applied over the mask to form one or more of the elements. In one variation of the present disclosure, one trace of the resistive heater layer 30′ is wider than a trace of the other resistive heater layer 30″ to provide for improved registration, or matching of the traces, when the adjacent substrates 24 and 26 are assembled together. This approach could also be employed with the peripheral sealing bands 60 and the local sealing bands 70, among other elements, and would be used with the “double-sided” application of material.

After each of the layers are applied and patterned, the substrates (22, 24, 26) are assembled together in step 250 and held together in a fixturing tool (not shown). The assembled substrates 22, 24, and 26 are joined with heat and pressure (step 260) in a controlled environment for a predetermined amount of time such that the material of each layer is solid-state bonded to secure the substrates (22, 24, 26) together. For example, a vacuum hot press furnace may be used at about 1,000° C. and about 1,000 psi for about two (2) hours to solid-state bond the substrates (22, 24, 26) together. As used herein, it should be understood that “solid-state” bonded (or bonding) means that a temperature of the material (e.g., nickel) remains below its liquidus temperature throughout the application of heat and pressure during the bonding process. This process should be distinguished from other methods, such as brazing, in which the temperature of the material exceeds its liquidus temperature. Solid-state bonding may also be referred to as diffusion bonding, however, the teachings of the present disclosure do not necessarily require that the material (e.g., nickel) of each electrically functioning layer diffuse into the other electrically functioning layer (with a two-sided application) or into the substrate material. Further, it should be understood that “liquidus” as used herein should be construed to include transient liquid phase bonding (TLP).

While the shaft 28 may be bonded to the assembled substrates (22, 24, 26) in the same process as set forth above, in one form, the shaft 28 is bonded to the substrates (22, 24, 26) in a separate process after the substrates (22, 24, 26) are solid-state bonded. In one form, the shaft 28 is also solid-state bonded to the substrates (22, 24, 26) using a similar process set forth above, thus resulting in a two-step solid-state bonding process to complete the overall heater assembly 20/pedestal. For example, at least one peripheral sealing band is embedded between and extends around a periphery of internal faces of the adjacent substrate 26 (or more generally, a heater plate) and the shaft 28. The peripheral sealing band in one form comprises a nickel material, which as set forth above is configured to secure and seal the heater plate and the shaft 28 together using a solid-state bonding process. It should be understood, however, that other joining/bonding techniques to join the shaft 28 may be employed while remaining within the scope of the present disclosure. Further, the shaft 28 may be integral with one of the adjacent substrates 26 while remaining within the scope of the present disclosure.

In one variation of the present disclosure, the pressure that is applied during the solid-state bonding is further controlled to adjust a size of the dielectric regions 100. In the solid-state bonding process in general, for nickel materials, the temperatures are between about 600° C. to about 1,455° C., the pressures are between about 10 psi to about 10,000 psi, with a total time at the bonding temperature (“soak time”) between about 0.25 hours to about 24 hours. The vacuum level is between about 1 and about 1E-7 Torr and may include an inert gas such as N₂ (nitrogen), He (helium), and Ar (argon), among others. Further, reducing atmospheres may be used to reduce oxides, such as by way of example hydrogen or carbon monoxide. It should be understood that these processing parameters will vary as a function of the size and construction of the layered assembly and thus should not be construed as limiting the scope of the present disclosure.

In still another form of the present disclosure, a method for repair is provided in which a layered assembly comprises at least two adjacent substrates (24/26) and at least one peripheral sealing band 60 embedded between and extending around a periphery of internal faces of the two adjacent substrates (24/26), similar to the peripheral sealing band 60 as previously described. In one form, the peripheral sealing band 60 comprises a nickel material configured to secure and seal the two adjacent substrates (24/26) together using the solid-state bonding process as described above. Further, the peripheral sealing band 60 may take on a different geometric configuration for this repair application, for example, being a continuous monolithic layer or a plurality of sealing bands disposed throughout the layer, which may or may not be “peripheral.”

In general, a pedestal that is in need of refurbishment is resurfaced, or ground down, to a specified flatness and surface roughness. In one example, a resurfaced substrate would represent the adjacent substrate 24 as illustrated and described above. Then, the peripheral sealing band 60 (or other sealing configuration) would be applied to one or both internal surfaces of the resurfaced substrate and a new upper substrate (i.e., the adjacent substrate 22 as illustrated and described above), and then this assembly would be solid-state bonded as described herein. Although nickel is one material that is used for the peripheral sealing band 60 in this variation, it should be understood that other materials such as aluminum, silicon, among others, and alloys thereof may be employed while remaining within the scope of the present disclosure. Further, the resurfacing process may go down even further through the assembly, for example even to the adjacent substrate 26 or the shaft 28 while remaining within the scope of the present disclosure.

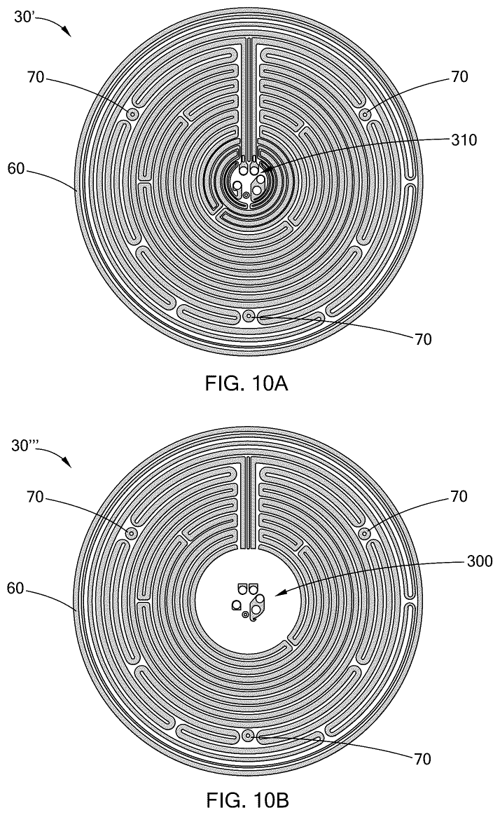

Referring now to FIGS. 10A and 10B, in conjunction with FIG. 3, another form of the present disclosure is illustrated, in which areas of the resistive heater layer 30″ on one adjacent substrate 26 are thermally decoupled from areas of the other resistive heater layer 30′ on the other adjacent substrate 24. More specifically, the first resistive heater layer 30′, which is applied to the lower surface of the adjacent substrate 24 is unchanged in this example. The second resistive heater layer 30″, which is applied to the upper surface of the adjacent substrate 26, defines a different trace pattern as shown, in which traces (also referred to as “circuitry”) are omitted near the electrical termination area 50, resulting in an unheated region 300, proximate the upper portion of the shaft 28. Accordingly thermal conduction from a central region 310 of the resistive heater layer 30′ to the unheated region 300 is inhibited, thereby providing a further means to locally control temperature and reduce thermal losses near the shaft 28. These and other variations of alternate trace patterns for the resistive heater layers, as well as the other electrically functioning layers, which are not mirror images of each other as described above, should be construed as falling within the scope of the present disclosure. For example, rather than omitting traces in certain areas, the traces may be reduced in thickness, thereby creating gaps between adjacent traces (for the two-sided application as described above), thereby thermally decoupling adjacent traces from each other.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A layered assembly for use in a controlled atmosphere chamber, the layered assembly comprising:
a plurality of substrates;
at least one electrically functioning layer embedded between two adjacent substrates of the plurality of substrates, the electrically functioning layer comprising a material configured to secure the two adjacent substrates together using a solid-state bonding process;
at least one electrical termination area integral with the at least one electrically functioning layer; and
at least one peripheral sealing band embedded between and extending around a periphery of internal faces two adjacent substrates, the at least one peripheral sealing band comprising a material configured to secure and seal the two adjacent substrates together using the solid-state bonding process,
wherein a plurality of dielectric regions are present between the two adjacent substrates and between edge boundaries of the at least one electrically functioning layer, the plurality of dielectric regions being sealed between the two adjacent substrates by the at least one peripheral sealing band.

2. The layered assembly according to claim 1, wherein the material of at least one of the electrically functioning layer and the peripheral sealing band comprises nickel.

3. The layered assembly according to claim 1, wherein the material of the electrically functioning layer is graded and has variable material properties along at least one dimension.

4. The layered assembly according to claim 1, wherein the electrically functioning layer is selected from the group consisting of a resistive heater, an RF antenna, and a clamping electrode.

5. The layered assembly according to claim 1, wherein the electrically functioning layer is a resistive heater and a temperature sensor.

6. The layered assembly according to claim 1, wherein each of the plurality of substrates comprise a ceramic material.

7. The layered assembly according to claim 6, further comprising an upper substrate disposed on one of the two adjacent substrates, the upper substrate comprising a different ceramic material than the ceramic material of the two adjacent substrates.

8. The layered assembly according to claim 7, wherein the two adjacent substrates are an aluminum nitride (AlN) material and the upper substrate is a high-grade AlN material.

9. The layered assembly according to claim 6, wherein the plurality of substrates comprise a beryllium oxide (BeO) material.

10. The layered assembly according to claim 1, wherein the two adjacent substrates comprise a plurality of apertures formed therethrough and the layered assembly further comprises local sealing bands disposed around a periphery of each of the plurality of apertures between the two adjacent substrates.

11. The layered assembly according to claim 10, wherein the material of the local sealing bands comprises nickel.

12. The layered assembly according to claim 1, further comprising an adhesion layer disposed between at least one of the two adjacent substrates and the at least one electrically functioning layer.

13. The layered assembly according to claim 12, wherein the adhesion layer is further disposed between at least one of the two adjacent substrates and the at least one peripheral sealing band.

14. The layered assembly according to claim 1, further comprising two electrically functioning layers embedded between two adjacent substrates of the plurality of substrates, each electrically functioning layer applied to each of the two adjacent substrates prior to the solid-state bonding process.

15. The layered assembly according to claim 14, wherein each electrically functioning layer comprises a trace, and a trace of one electrically functioning layer is wider than a trace of the other electrically functioning layer.

16. The layered assembly according to claim 1, further comprising two peripheral sealing bands embedded between two adjacent substrates of the plurality of substrates, each peripheral sealing band applied to each of the two adjacent substrates prior to the solid-state bonding process.

17. The layered assembly according to claim 16, wherein a band width of one peripheral sealing band is wider than a band width of the other peripheral sealing band.

18. The layered assembly according to claim 1, further comprising a plurality of material islands disposed within the dielectric regions, wherein the material islands are not electrically live.

19. The layered assembly according to claim 1, further comprising a shaft secured to a lower side of one of the two adjacent substrates.

20. The layered assembly according to claim 1, wherein the seal is hermetic.

21. The layered assembly according to claim 1, wherein the at least one electrically functioning layer comprises a resistive heater having a plurality of zones.

22. The layered assembly according to claim 1, further comprising a plurality of zones of resistive heaters disposed in different layers within the plurality of substrates.
